(19) United States
(12) Patent Application Publication
(10) Pub. No.: US 2020/0118859 A1
(43) Pub. Date: Apr. 16, 2020

(54) APPARATUS FOR PROCESSING SUBSTRATE

(71) Applicants: KABUSHIKI KAISHA TOSHIBA, Minato-ku (JP); TOSHIBA ELECTRONIC DEVICES & STORAGE CORPORATION, Minato-ku (JP)

(72) Inventors: Hiroshi SANDA, Yokohama (JP); Kai HU, Nonoichi (JP); Hironobu SHIBATA, Nonoichi (JP); Koji FUJIBAYASHI, Chiba (JP); Yoshikuni TATEYAMA, Hiratsuka (JP); Hideto YABUI, Sumida (JP)

(73) Assignees: KABUSHIKI KAISHA TOSHIBA, Minato-ku (JP); TOSHIBA ELECTRONIC DEVICES & STORAGE CORPORATION, Minato-ku (JP)

(21) Appl. No.: 16/299,464

(22) Filed: Mar. 12, 2019

(30) Foreign Application Priority Data
Oct. 16, 2018 (JP) 2018-194754

(51) Int. Cl. H01L 21/683; H01J 37/32; C23C 16/458; C23C 14/50

(52) U.S. Cl. CPC H01L 21/6833; H01J 37/32715; H01J 2237/2007; C23C 14/50; C23C 16/4586

(57) ABSTRACT

A process apparatus includes an electrostatic chuck disposed at a substrate holder. The electrostatic chuck includes a dielectric and an electrode. The electrode is disposed in an interior of the dielectric. The apparatus further includes a circuit electrically connected to the electrode of the electrostatic chuck and a first earth wire electrically connected to the circuit. The first earth wire is shielded by a metal with an electrically insulating cover interposed.

### CROSS-REFERENCE TO RELATED APPLICATIONS

This application is based upon and claims the benefit of priority from Japanese Patent Application No. 2018-194754, filed on Oct. 16, 2018; the entire contents of which are incorporated herein by reference.

### FIELD

Embodiments relate to an apparatus for processing a substrate.

### BACKGROUND

Many process apparatuses include an electrostatic chuck for fixing a substrate on a substrate holder, and process the substrate such as a semiconductor wafer or the like at reduced pressure. It is important for the process apparatus to hold the substrate stably by the electrostatic chuck to ensure the reproducibility of processing.

### BRIEF DESCRIPTION OF THE DRAWINGS

FIG. 1 is a schematic view showing a process apparatus according to a first embodiment;

FIGS. 2A and 2B are schematic views showing an operation of the process apparatus according to the first embodiment;

FIG. 3 is a graph showing characteristics of the process apparatus according to the first embodiment;

FIGS. 4A and 4B are schematic views showing process apparatuses according to modifications of the first embodiment;

FIG. 5 is a schematic view showing a shield structure of the earth wire of the process apparatus according to the first embodiment; and

FIG. 6 is a schematic view showing a process apparatus according to a second embodiment.

### DETAILED DESCRIPTION

According to an embodiment, a process apparatus includes an electrostatic chuck disposed at a substrate holder. The electrostatic chuck includes a dielectric and an electrode. The electrode is disposed in an interior of the dielectric. The apparatus further includes a circuit electrically connected to the electrode of the electrostatic chuck and a first earth wire electrically connected to the circuit. The first earth wire is shielded by a metal with an electrically insulating cover interposed.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

### First embodiment

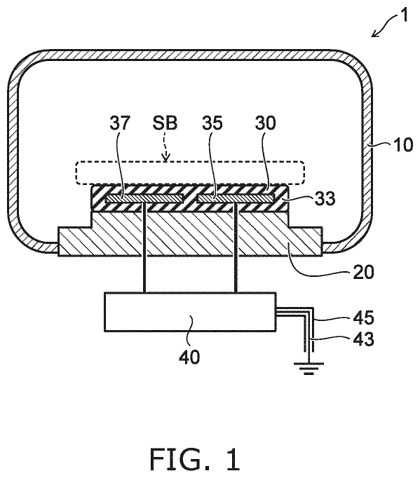

FIG. 1 is a schematic view showing a process apparatus 1 according to a first embodiment. The process apparatus 1 is, for example, a sputtering apparatus, a dry etching apparatus, a plasma CVD apparatus, etc. For example, the process apparatus 1 is used to process a substrate such as a semiconductor wafer, a glass substrate, a resin disk, etc.

As shown in FIG. 1, the process apparatus 1 includes a pressure-reduction chamber 10, a substrate holder 20, an electrostatic chuck 30, and a clamp circuit 40. For example, the electrostatic chuck 30 is disposed on the substrate holder 20 in the interior of the pressure-reduction chamber 10. A substrate to be processed (hereinafter, the substrate SB) is placed on the electrostatic chuck 30.

The electrostatic chuck 30 includes, for example, a dielectric 33, an electrode 35, and an electrode 37. The electrode 35 and the electrode 37 are disposed in the interior of the dielectric 33. The dielectric 33 includes, for example, a ceramic such as aluminum oxide, aluminum nitride, or the like, a resin such as polyimide, etc.

The substrate SB is placed to oppose the electrode 35 and the electrode 37 with a portion of the dielectric 33 interposed. The substrate SB is attracted and fixed to the dielectric 33 by a Coulomb force, a Johnsen-Rahbek force, a gradient force, or the like acting between the electrode 35 and the substrate SB and between the electrode 37 and the substrate SB, where the prescribed potentials are applied to the electrodes 35 and 37.

Here, a bipolar electrostatic chuck in which electrodes of the two polarities are disposed in the interior of the dielectric 33 is shown as an example; but the embodiments are not limited thereto. For example, a monopolar electrostatic chuck may be used in which an electrode is disposed in the interior of the dielectric 33, and one polarity potential of positive or negative is applied thereto.

The clamp circuit 40 is disposed outside the pressure-reduction chamber 10 and is electrically connected to the electrode 35 and the electrode 37. The clamp circuit 40 supplies prescribed potentials to the electrode 35 and the electrode 37. Also, the clamp circuit 40 is grounded by an earth wire 43.

For example, the earth wire 43 is shielded by a metal foil 45. For example, the earth wire 43 is covered with an insulating resin and is covered with the metal foil 45. Also, a shielded wire such as a coaxial cable or the like can be used as the earth wire 43 instead of being shielded by the metal foil 45.

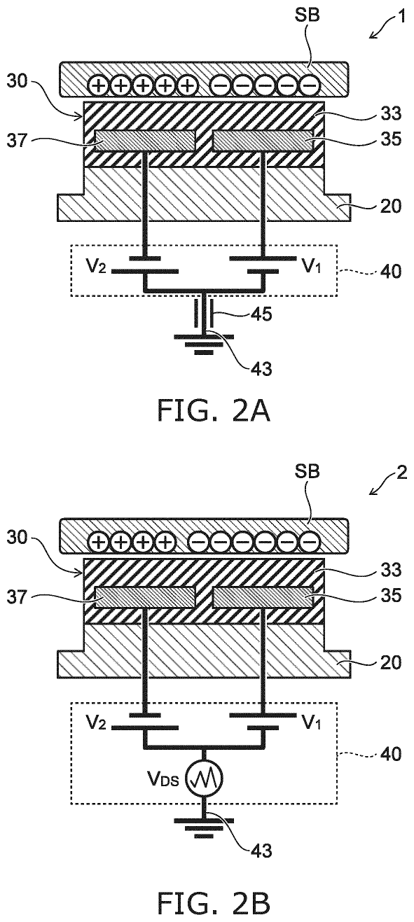

FIGS. 2A and 2B are schematic views showing an operation of the process apparatus according to the first embodiment. FIG. 2A is a schematic view showing the process apparatus 1 according to the embodiment; and FIG. 2B is a schematic view showing a process apparatus 2 according to a comparative example.

As shown in FIG. 2A, a positive potential V₁ is supplied to the electrode 35 of the electrostatic chuck 30; and a negative potential V₂ is supplied to the electrode 37. Thereby, a negative charge is induced in the portion of the substrate SB opposing the electrode 35; and a positive charge is induced in the portion of the substrate SB opposing the electrode 37. As a result, for example, the substrate SB is fixed on the electrostatic chuck 30 by the Coulomb force acting between the electrode 35 and the substrate SB and between the electrode 37 and the substrate SB. For example, the absolute value of the negative potential V₂ is equal to the positive potential V₁; and the substrate SB is held more stably by a uniform chucking force.

In the process apparatus 2 shown in FIG. 2B, the earth wire 43 of the clamp circuit 40 is unshielded. Therefore, in the clamp circuit 40, the earth wire 43 becomes an antenna and is affected by electromagnetic noise generated outside. For example, an induced current is generated by the electromagnetic noise in the earth wire 43; and the parasitic capacitance of the clamp circuit 40 is charged. Therefore, a noise voltage V_{DS} is induced inside the clamp circuit 40 and is superimposed onto, for example, the positive potential V₁ and the negative potential V₂ supplied to the electrostatic chuck 30.

For example, in the case where the noise voltage V_{DS} is a positive voltage, the positive potential Vᵢ of the electrode 35 increases; and the negative potential V₂ of the electrode 37 decreases. Therefore, for example, the Coulomb force that acts between the electrode 35 and the substrate SB increases; and the Coulomb force that acts between the electrode 37 and the substrate SB decreases. In other words, the force is biased, which holds the substrate SB on the electrostatic chuck 30. Thereby, the process conditions change in the surface of the substrate fixed on the electrostatic chuck 30; and there are cases where the substrate SB cannot be processed uniformly. For example, the heat dissipation to the outside via the electrostatic chuck 30 and the substrate holder 20 is biased; and the temperature distribution of the substrate SB becomes nonuniform. As a result, there are cases where the etching rate of the substrate and/or the deposition rate of a film formed on the substrate become nonuniform.

Also, when moving the substrate SB from the electrostatic chuck 30, a negative potential is supplied to the electrode 35; and a positive potential is supplied to the electrode 37. Thereby, the charge that is induced inside the substrate SB is dispersed; and the chucking force that acts on the substrate SB disappears. When the noise voltage V_{DS} is induced inside the clamp circuit 40, the dispersion of the charge of the substrate SB is delayed; and there are cases where a so-called transfer error occurs in which the substrate SB cannot be detached from the electrostatic chuck 30.

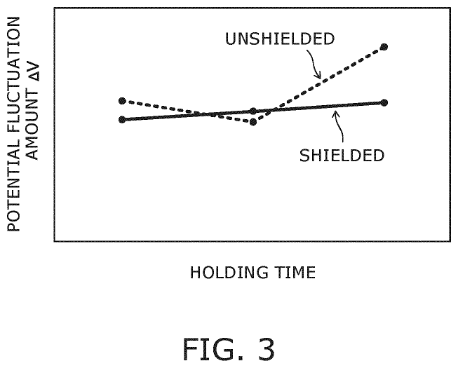

FIG. 3 is a graph showing characteristics of the process apparatus 1 according to the first embodiment. The horizontal axis is the time that the substrate SB is held on the electrostatic chuck 30; and the vertical axis is a potential variation amount ΔV of the electrode 35 and the electrode 37.

FIG. 3 shows the potential variation amounts ΔV in the case where the earth wire 43 is shielded and in the case where the earth wire 43 is unshielded. Here, for example, the potential variation amount ΔV is the change amount of the potentials supplied to the electrode 35 and the electrode 37. In other words, the potential of the electrode 35 is V₁+ΔV; and the potential of the electrode 37 is V₂+ΔV.

As shown in FIG. 3, the potentials of the electrode 35 and the electrode 37 vary greatly in the case where the earth wire 43 is unshielded. On the other hand, the potentials of the electrode 35 and the electrode 37 are stable in the case where the earth wire 43 is shielded. Thus, by shielding the earth wire 43, the potentials of the electrode 35 and the electrode 37 can be stabilized; and the substrate SB can be held stably on the electrostatic chuck 30. As a result, the reproducibility of the processing conditions of the substrate SB in the process apparatus 1 can be improved; and the transfer errors can be avoided.

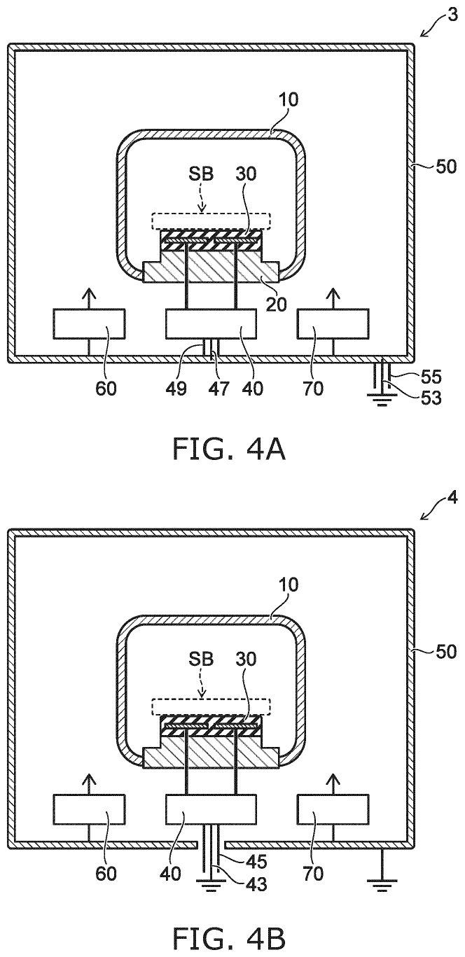

FIGS. 4A and 4B are schematic views showing process apparatuses 3 and 4 according to modifications of the first embodiment. The process apparatuses 3 and 4 further include a housing 50 that houses the pressure-reduction chamber 10. Also, multiple circuits that include the clamp circuit 40 are disposed in the interior of the housing 50.

In the process apparatus 3 shown in FIG. 4A, the housing 50 is grounded via an earth wire 53. For example, the earth wire 53 is shielded by a metal foil 55. The earth wire 53 may be a shielded wire such as a coaxial cable, etc.

The pressure-reduction chamber 10, the clamp circuit 40, a high frequency circuit 60, and a drive circuit 70 are disposed in the interior of the housing 50. The clamp circuit 40 is electrically connected to the electrostatic chuck 30 disposed in the interior of the pressure-reduction chamber 10. For example, the high frequency circuit 60 is electrically connected to a discharge electrode (not illustrated) disposed in the interior of the pressure-reduction chamber 10 and is used to excite plasma in the interior of the pressure-reduction chamber 10. For example, the drive circuit 70 drives a transfer system (not illustrated) that transfers the substrate SB, a gas supply system (not illustrated) that supplies gas to the interior of the pressure-reduction chamber 10, etc.

The clamp circuit 40, the high frequency circuit 60, and the drive circuit 70 each are grounded via the housing 50. The clamp circuit 40 is electrically connected to the housing 50 via an earth wire 47. Further, for example, the earth wire 47 is shielded by a metal foil 49. The earth wire 47 may be a shielded wire such as a coaxial cable, etc.

For example, the clamp circuit 40, the high frequency circuit 60, and the drive circuit 70 are protected from electromagnetic noise from the outside when the housing 50 has a structure capable of shielding the electromagnetic noise. For example, the clamp circuit 40 is shielded by the metal foil 49 covering the earth wire 47 and is configured to suppress the effects of the electromagnetic noise generated in the high frequency circuit 60 or the drive circuit 70. In the case where there is no generation source of electromagnetic noise in the interior of the housing 50, the shielding by the metal foil 49 may be omitted.

Even in the case where the housing 50 does not have a shield function, the effects of the electromagnetic noise on the clamp circuit 40 can be suppressed by shielding the earth wire 47 with the metal foil 49 and by shielding the earth wire 53 with the metal foil 55.

In the process apparatus 4 shown in FIG. 4B, the clamp circuit 40 is directly grounded via the earth wire 43. For example, the earth wire 43 is shielded by the metal foil 45. Thereby, it is possible to suppress the effects of the electromagnetic noise on the clamp circuit 40, which come from the outside or is generated by the high frequency circuit 60 or the drive circuit 70.

Thus, in the process apparatuses 3 and 4 according to the embodiment, the effects of the electromagnetic noise on the clamp circuit 40 can be suppressed; and the substrate SB can be held stably on the electrostatic chuck 30. Also, the transfer error can be avoided when moving the substrate SB from the electrostatic chuck 30.

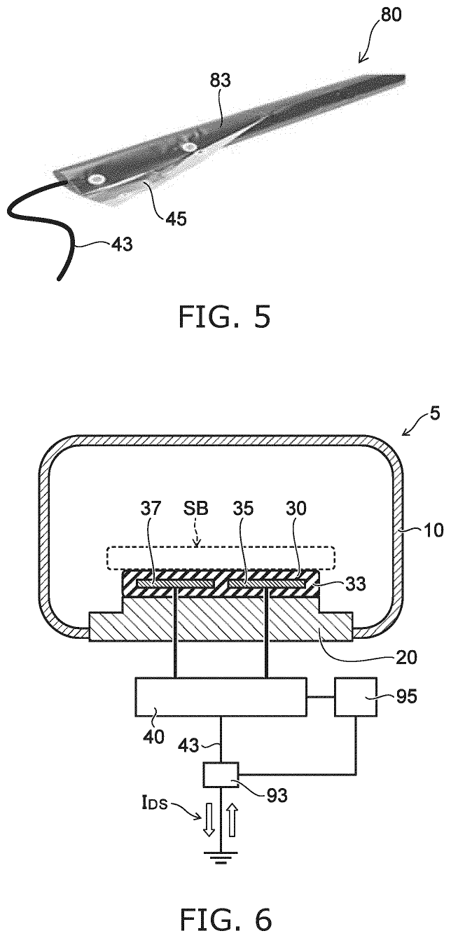

FIG. 5 is a schematic view showing a shield structure 80 of the earth wire 43 of the process apparatus according to the first embodiment. For example, the earth wire 43 is covered with an insulating resin. The earth wire 43 with the insulating resin is covered with a shield cover 83. The shield cover 83 has a structure in which a metal foil, e.g., a copper foil, an aluminum foil, or the like is adhered inside a cover made of a resin.

### Second Embodiment

FIG. 6 is a schematic view showing a process apparatus 5 according to a second embodiment. The process apparatus 5 includes the pressure-reduction chamber 10, the substrate holder 20, the electrostatic chuck 30, and the clamp circuit 40. The process apparatus 5 also has a configuration suppressing the effects of the electromagnetic noise on the electrostatic chuck 30.

As shown in FIG. 6, the substrate holder 20 is configured to hold a substrate in the interior of the pressure-reduction chamber 10. The electrostatic chuck 30 is disposed on the substrate holder 20 and fixes the substrate SB to the substrate holder 20. The clamp circuit 40 is electrically connected to the electrode 35 and the electrode 37 of the electrostatic chuck 30. The clamp circuit 40 is grounded via the earth wire 43. In the example, a shield is not provided at the earth wire 43.

The process apparatus 5 further includes a current sensor 93 and an offset control circuit 95. The current sensor 93 detects the current flowing in the earth wire 43 of the clamp circuit 40. The current sensor 93 is, for example, a clamp meter. The offset control circuit 95 is configured to add a compensation voltage for maintaining the output of the clamp circuit 40 at a constant level according to the output of the current sensor 93.

For example, in the case where an induced current I_{DS} is induced in the earth wire 43 by electromagnetic noise, the current sensor 93 outputs a signal corresponding to the magnitude and the direction of the induced current I_{DS}. The offset control circuit 95 receives the output of the current sensor 93 and, for example, outputs a compensation voltage to the clamp circuit 40, which is added to cancel the noise voltage V_{DS} induced by the induced current I_{DS}.

For example, the offset control circuit 95 supplies the compensation voltage for canceling the noise voltage V_{DS} based on a correlation between the induced current I_{DS} and the noise voltage V_{DS}; and the clamp circuit 40 is configured to output the prescribed voltages V₁ and V₂ (referring to FIG. 2B) to which the compensation voltage is added. For example, the offset control circuit 95 includes a memory portion storing the correlation between the induced current I_{DS} and the noise voltage V_{DS}; and the offset control circuit 95 outputs the compensation voltage corresponding to the output of the current sensor 93. Instead of the current sensor 93, the offset control circuit 95 may be configured to detect a potential of the interior of the clamp circuit 40 and to add a compensation voltage to the output of the clamp circuit 40, which is based on a correlation between the potential and the noise voltage V_{DS}.

Thereby, the effects of the electromagnetic noise on the potentials supplied to the electrode 35 and the electrode 37 of the electrostatic chuck 30 are reduced; and it is possible to stably hold the substrate SB. As a result, the reproducibility of the process conditions in the process apparatus 5 can be improved; and faults such as transfer errors, etc., can be avoided.

Although the clamp circuit 40 and the offset control circuit 95 are separated from each other in the example recited above, the embodiment is not limited thereto. For example, the clamp circuit 40 and the offset control circuit 95 may be combined in a circuit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A process apparatus, comprising:
an electrostatic chuck disposed at a substrate holder, the electrostatic chuck including a dielectric and electrode, the electrode being disposed in an interior of the dielectric;
a circuit electrically connected to the electrode of the electrostatic chuck; and
a first earth wire electrically connected to the circuit, the first earth wire being shielded by a metal with an electrically insulating cover interposed.

2. The apparatus according to claim 1, further comprising a housing surrounding the substrate holder and the circuit,
the housing being grounded by the first earth wire,
the circuit being electrically connected to the housing via a second earth wire and being grounded via the housing.

3. The apparatus according to claim 2, wherein the second earth wire is shielded by a metal with an electrically insulating cover interposed.

4. The apparatus according to claim 1, wherein the circuit is directly grounded by the first earth wire.

5. The apparatus according to claim 4, further comprising a housing surrounding the substrate holder and the circuit,
the first earth wire being electrically isolated from the housing and being grounded outside the housing.

6. The apparatus according to claim 1, wherein the electrostatic chuck is disposed in an interior of a pressure-reduction chamber.

7. The apparatus according to claim 1, wherein the metal is provided with a shape of metal foil covering an exterior of the electrically insulating cover.

8. The apparatus according to claim 1, wherein the first earth wire is a coaxial cable.

9. The apparatus according to claim 1, wherein
the electrode of the electrostatic chuck is provided in a plurality, the plurality of electrodes including a first electrode and a second electrode, the first electrode being biased at a first voltage of first polarity, the second electrode being biased at a second voltage of second polarity different from the first polarity.

10. A process apparatus, comprising:
an electrostatic chuck including a dielectric and electrode and being disposed at a substrate holder, the electrode being disposed in an interior of the dielectric;
a first circuit electrically connected to the electrode of the electrostatic chuck;
an earth wire electrically connected to the first circuit;
a current sensor detecting a current flowing in the earth wire; and
a second circuit electrically connected to the first circuit and the current sensor,
the second circuit receiving a current value detected by the current sensor and adding a compensation voltage to an output of the first circuit, the compensation voltage being based on a correlation between the current value and a change amount of a potential output, the potential output being outputted from the first circuit to the electrode of the electrostatic chuck.

11. The apparatus according to claim 10, wherein the current sensor is a clamp meter.

12. The apparatus according to claim 10, wherein the first circuit and the second circuit are provided as one body.

13. The apparatus according to claim 10, wherein
the electrode of the electrostatic chuck is provided in a plurality, the plurality of electrodes including a first electrode and a second electrode, the first electrode being biased at a first voltage of first polarity, the second electrode being biased at a second voltage of second polarity different from the first polarity.
